(19) United States
(12) Patent Application Publication
(10) Pub. No.: US 2003/0110430 A1
(43) Pub. Date: Jun. 12, 2003

(54) Method and system for use of a field programmable gate array (FPGA) function within an application specific integrated circuit (ASIC) to enable creation of a debugger client within the ASIC

(75) Inventors: Robert Thomas Bailis, Cary, NC (US); Charles Edward Kuhlmann, Raleigh, NC (US); Charles Steven Lingafelt, Durham, NC (US); Ann Marie Rincon, Burlington, VT (US)

Correspondence Address: IBM CORPORATION, PO BOX 12195, DEPT 9CCA, BLDG 002, RESEARCH TRIANGLE PARK, NC, 27709, US

(73) Assignee: International Business Machines Corporation, Armonk, NY (US)

(21) Appl. No.: 10/016,449

(22) Filed: Dec. 10, 2001

(51) Int. Cl. G01R 31/28

(52) U.S. Cl. 714/725

(57) ABSTRACT

An application specific integrated circuit (ASIC) is disclosed. The ASIC includes a standard cell. The standard cell includes a plurality of logic functions and at least one bus coupled to at least a portion of the logic functions. The standard cell also includes a plurality of internal signals from the plurality of logic functions and a field programmable gate array (FPGA) function coupled to the at least one bus and at least a portion of the plurality of internal signals. The FPGA function includes a debug client function that observes and manipulates the at least one bus and the plurality of internal signals. A system and method in accordance with the present invention utilizes a debug function within a standard cell design to create an internal-to-the-ASIC debugging (software, hardware or both) function. The system and method is provided by connection of internal buses and signals of interest to a debug client function within the FPGA function. The debug client function observes and, if needed, manipulates internal buses and signals and communicates with an external to the ASIC debugging system.

### CROSS-RELATED APPLICATIONS

The present application is related to the following listed seven applications: Ser. No. ______ (RPS920010125US1) entitled “Field Programmable Network Processor and Method for Customizing a Network Processor;” Ser. No. ______ (RPS920010126US1), entitled “Method and System for Use of an Embedded Field Programmable Gate Array Interconnect for Flexible I/O Connectivity;” Ser. No. ______ (RPS 920010128US1), entitled “Method and System for Use of a Field Programmable Function Within an Application Specific Integrated Circuit (ASIC) To Access Internal Signals for External Observation and Control;” Ser. No. ______ (RPS920010129US1), entitled “Method and System for Use of a Field Programmable Interconnect Within an ASIC for Configuring the ASIC;” Ser. No. ______ (RPS920010130US1), entitled “Method and System for Use of a Field Programmable Function Within a Chip to Enable Configurable I/O Signal Timing Characteristics;” Ser. No. ______ (RPS920010131US1), entitled “Method and System for Use of a Field Programmable Function Within a Standard Cell Chip for Repair of Logic Circuits;” and Ser. No. ______ (RPS920010132US1), entitled “Method and System for Use of a Field Programmable Gate Array 9FPGA) Cell for Controlling Access to On-Chip Functions of a System on a Chip (S)C) Integrated Circuit;” assigned to the assignee of the present application, and filed on the same date.

### FIELD OF THE INVENTION

The present invention relates generally to an application specific integrated circuit (ASIC) and specifically to providing an FPGA function to allow for the use of a debug client within the ASIC.

### BACKGROUND OF THE INVENTION

In today's (logical) ASIC test environment, application specific integrated circuits (ASICs) are extremely dense with various functions while having limited I/O with respect to those functions. Often, there are significant, complex functions connection with only internal ASIC buses and signal paths, which are not exposed via an I/O pin. Further, due to the density and complexity of functions, it would not be practical to bring out all needed debug functions, as this would result in potentially thousands of I/O pins.

Historically, functional entities were embodied in multiple ASICs with an exposed bus and signal paths between the ASICs (functions). This enabled the use of logical analyzers, logic debuggers and like tools to be used to debug the system. This is not possible with today's ASICs as there is no physical method available to place the debuggers on an internal-to-the-ASIC bus and no method to disconnect and tie up or down internal-to-the-ASIC signal paths.

Accordingly, what is needed is a system and method for allowing the debugging of an ASIC via access to the ASIC's internal signals. The present invention addresses such a need.

### SUMMARY OF THE INVENTION

An application specific integrated circuit (ASIC) is disclosed. The ASIC includes a standard cell. The standard cell includes a plurality of logic functions and at least one bus coupled to at least a portion of the logic functions. The standard cell also includes a plurality of internal signals from the plurality of logic functions and a field programmable gate array (FPGA) function coupled to the at least one bus and the plurality of internal signals. The FPGA function includes a debug client function that observes and manipulates the at least one bus and the plurality of internal signals.

A system and method in accordance with the present invention utilizes a debug function within a standard cell design to create an internal-to-the-ASIC debugging (software, hardware or both) function. The system and method is provided by connection of internal buses and signals of interest to a debug client function within the FPGA function. The debug client function observes and, if needed, manipulates internal buses and signals and communicates with an external to the ASIC debugging system.

### BRIEF DESCRIPTION OF THE DRAWINGS

FIG. 1 illustrates the placement of an FPGA function into a representative standard cell design.

FIG. 2 illustrates a logical view of the internals of the debug client function in accordance with the present invention.

FIG. 3 illustrates a debug system in accordance with the present invention.

### DETAILED DESCRIPTION

The present invention relates generally to an application specific integrated circuit (ASIC) and specifically to providing an FPGA function to allow for the debug via the ASIC. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

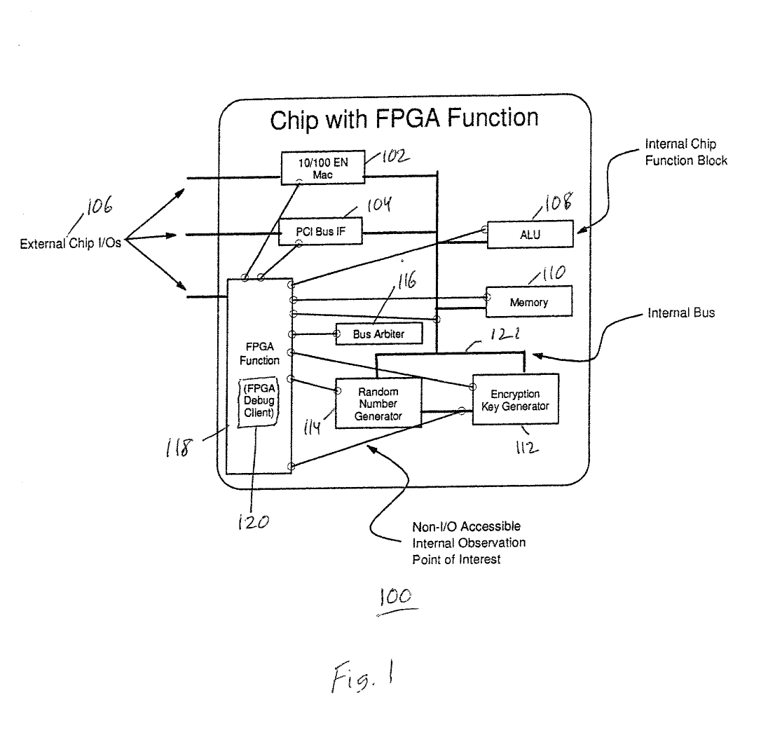

FIG. 1 illustrates the placement of an FPGA function into a representative standard cell design 100. In this embodiment, the standard cell design includes a media access controller (MAC) 102, a PCI bus interface 104, arithmetic logic unit (ALU) 108, a memory 110, a bus arbiter 116, a random number generator 114, and encryption key generator 112. A plurality of external I/Os 106 are provided to the MAC 102, the PCI bus interface 104 and to the FPGA function 118. In addition, there is an internal bus 121 between the generator 114 and the generator 112. An FPGA debug client 120 is within the FPGA function 118. Although specific functions and buses are illustrated in the standard cell, one of ordinary skill in the art recognizes that a variety of functions could be utilized and that use would be within the spirit and scope of the present invention.

As is seen, all internal buses and signals of interest are “bused” or connected to the FPGA function 118. In the preferred embodiment, the FPGA function 118 itself has external I/O connectivity. An alternative embodiment would be to reuse an existing I/O structure, such as a PCI bus, but this has inherent disadvantages when trying to debug a function that also uses that I/O structure. As has been described above, the FPGA function 118 includes a debug client function 120 thereafter. The debug client function 120 can be utilized advantageously to observe and manipulate the buses and internal signals of the standard cell. For a further description of the features of the debug client function 120, refer now to the following description in conjunction with the accompanying figures.

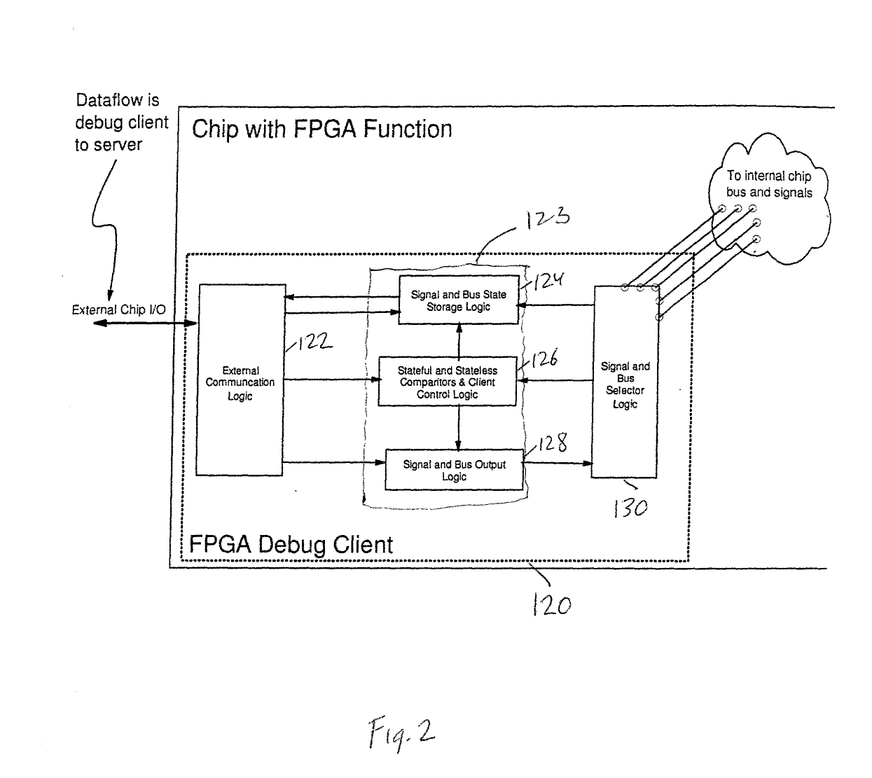

FIG. 2 illustrates a logical view of the internals of the debug client function 120 in accordance with the present invention. It is not meant to illustrate how one would physically program this area. The debug client function 120 includes the external communicator logic 122, which communicates with interface logic 123. This interface logic 123 includes signal and bus state storage logic 124, stateful and stateless comparators and client control logic 126 and signal and bus output logic 128. The logic 126 communicates with the logic 124 and logic 128. A signal and bus selector logic 130 communicates with the interface logic 123 and with the internal signals and bus. The function and features of each of the logic elements of the debug client function 120 are described below.

Signal and Bus Selector Logic Function Block 130

The signal and bus selector logic function block 130 can be embodied either as physical bus selectors gates using standard bus selector techniques in which all signals are sent through this selector logic and the FPGA logic then selects the ones of interest or as virtual selection (all signals of interest are available at a particular input point, tied up or down as appropriate, but only those points of interest are connected to and enabled when the FPGA is programmed—de facto selection).

Interface Logic 123

Signal and Bus State Storage Logic Function Block 124

The signal and bus state storage logic function block 124 stores the state of the signals of interest (“of interest” is defined through a debugger server) for later retrieval by a debugger server.

Stateful and Stateless Comparators and Client Control Logic Function Block 126

The stateful and stateless comparators and client control logic function block 126 is the logic that compares the signals of interest with the “trigger” pattern that is down-loaded from the debugger server and upon a match, directs the signal and bus state storage logic function block 124 to store the signals of interest.

Signal and Bus Output Logic Function Block 128

The signal and bus output logic function block 128 is logic that the debugger server uses to manipulate the internal signals on the ASIC. This may include clock signals, for single step debugging and may be the result of a logical expression derived from the control logic, i.e., when the write strobe on the internal RAM goes active and the RAM address bus has address “ABCDEF42”, then halt an internal ASIC clock.

External Communication Logic Function Block 122

The external communication logic function block 122 provides the external I/O function for the debug client to communicate with the debug server.

Debug System

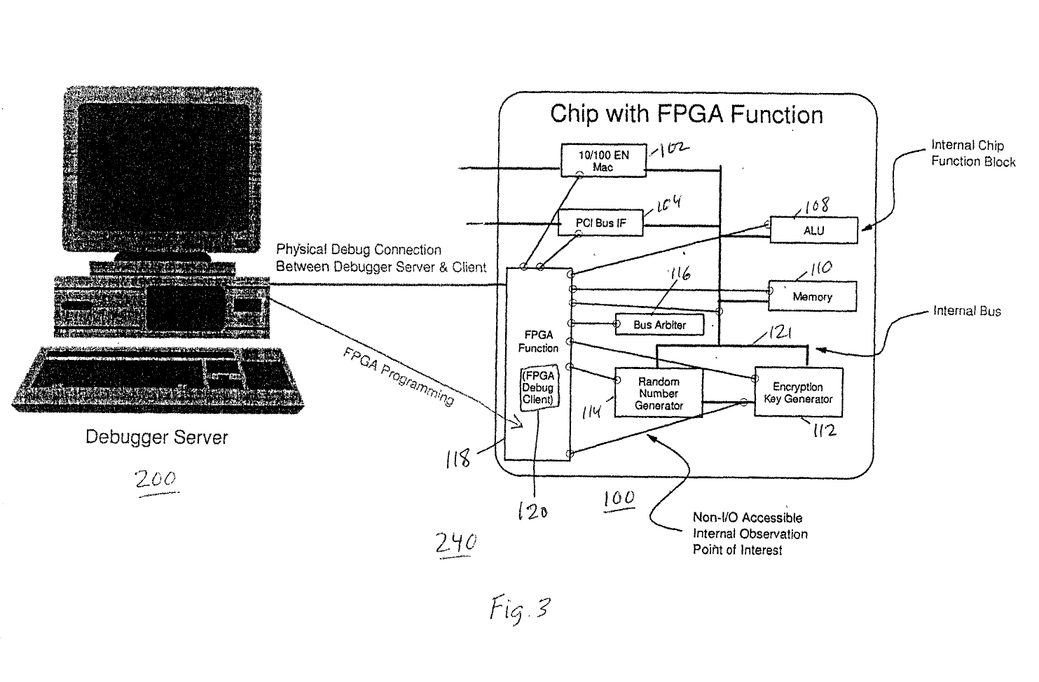

FIG. 3 illustrates a debug system 240 in accordance with the present invention. Note that the preferred embodiment of the debugger server 200 is a general purpose processing system running a debugger application (a PC). The communications link between the systems does not have to be as rapid as the internal ASIC communications links because of the debug client.

The debug client function 120 contains either an independent or dependent debugger client. The preferred embodiment is a simple dependent client, with each debugging session information downloaded (the FPGA is “programmed”) by the debugger server 240, much like the model of physically connected leads from external buses to a logic analyzer, then setting a trigger point and observing the system. Upon trigger, the system server 240 will capture selected information. This same concept is embodied in the independent debugger client with the addition that one may wish to set a bus or signal to a know value, either before the observation period or as a result of an observed action. This same process could be used to hold part or all of an ASIC's clocks in a known state or to hold part or all of an ASIC's functional areas in reset modes.

Note that as described, this system could be used to debug hardware values (e.g., the value of signals within a hardware function block). However, a significant extension can be made by altering the way that the debugger server 240 uses the debug client function, which will enable this same concept to be used to debug software. If instead of triggering based on hardware values, the triggers are based on software values (assuming the debug client function's ability to manage the instruction pointer logic within the ASIC and to observer and manipulate registers and memory) then one can create a debugging system for software. Given the complexities of software systems today and the often wholly within the ASIC software interfaces, this could be of more value than hardware debugging.

A first distinguishing feature between a system and method in accordance with the present invention and achieving a similar function within the hard-coded portion of a standard ASIC is that this method allows the user to change the software or hardware debug client after the ASIC has been cast into silicon. In addition, the different producers of the ASIC debugger system can place their own unique value added client in the ASIC, thus with one ASIC, enabling the creation of multiple debuggers from multiple different companies.

A second distinguishing feature between a system and method in accordance with the present invention and achieving a similar function within the hard-coded portion of a standard ASIC is that this method allows the user to change the debug process after the ASIC has been cast into silicon. It is not possible to know all possible debug considerations when the ASIC is created. As the complexity of the ASICs increase and the programmability (more software bugs that must be found) of the ASICs increase, the ability to change the debug process will become increasingly important.

An additional advantage is that this process allows the independent development of the software debugging system with respect to the ASIC development. This would allow an ASIC vendor to define the FPGA characteristics and the available internal signals to a third party debugger developer, thus:

1. allowing parallel development of the ASIC and the debugging tools

2. allowing the debugging tools to be developed by a third party, saving the ASIC vendor the resource expenditure.

Another advantage is that the same ASIC can simultaneously support multiple debugging systems by different companies. For example, if two manufacturers both wanted to build a FPGA embodied debugger client that worked with their proprietary system, they could both do that with the same ASIC.

A system and method in accordance with the present invention utilizes a debug function within a standard cell design to create an internal-to-the-ASIC debugging (software, hardware or both) function. The system and method is provided by connection of internal buses and signals of interest to a debug client function within the FPGA function. The debug client function observes and, if needed, manipulates internal buses and signals and communicates with an external to the ASIC debugging system.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. An application specific integrated circuit (ASIC) comprising:
a standard cell, the standard cell including a plurality of logic functions;
at least one bus coupled to at least a portion of the logic functions;
a plurality of internal signals from the plurality of logic functions; and
a field programmable gate array (FPGA) function coupled to the at least one bus and the plurality of internal signals, the FPGA function including a debug client function that observes and manipulates the at least one bus and the plurality of internal signals.

2. The ASIC of claim 1 wherein the at least one bus comprises an internal bus.

3. The ASIC of claim 2 wherein the debug client function observes and manipulates at least one point of interest on the standard cell.

4. The ASIC of claim 1 wherein the debug client function is programmed by a server.

5. The ASIC of claim 1 wherein the debug client function further includes:
an external communicator logic function for receiving and transmitting information to a server;
selector logic coupled to the at least one bus and the plurality of internal signals, and
an interface logic coupled between the external communicator logic and the selector logic for providing communication therebetween.

6. The ASIC of claim 5 wherein the interface logic comprises:
a storage logic function for storing a state of signals of interest from the selector logic and providing the state to a server;
a comparator logic function coupled to the storage logic function for comparing the signals of interest from the selector block function; and
an output logic function coupled to the comparator logic function for controlling the internal signals on the ASIC.

7. The ASIC of claim 4 wherein the server utilizes the debug client to debug hardware within at least one of the plurality of logic functions.

8. The ASIC of claim 4 wherein the server utilizes the debug client to debug software within at least one of the plurality of logic functions.

9. A debug client function within an application specific integrated circuit (ASIC), the debug client function being within a field programmable gate array (FPGA) function; the client debug function comprising:
an external communicator logic function for receiving and transmitting information concerning a plurality of signals of the ASIC to a server;
selector logic coupled to the at least one bus of the ASIC and the plurality of internal signals, and
an interface logic coupled between the external communicator logic and the selector logic for providing communication therebetween.

10. The ASIC of claim 9 wherein the at least one bus comprises an internal bus.

11. The ASIC of claim 9 wherein the debug client function observes and manipulates at least one point of interest on the standard cell.

12. The ASIC of claim 9 wherein the debug client function is programmed by a server.

13. The ASIC of claim 9 wherein the interface logic comprises:
a storage logic function for storing a state of signals of interest from the selector logic and providing the state to a server;
a comparator logic function coupled to the storage logic function for comparing the signals of interest from the selector block function; and
an output logic function coupled to the comparator logic function for controlling the internal signals on the ASIC.

14. The ASIC of claim 12 wherein the server utilizes the debug client to debug hardware within at least one of the plurality of logic functions.

15. The ASIC of claim 12 wherein the server utilizes the debug client to debug software within at least one of the plurality of logic functions.
